(19) United States
(12) Patent Application Publication
(10) Pub. No.: US 2010/0239444 A1
(43) Pub. Date: Sep. 23, 2010

(54) LAYERED PIEZOELECTRIC ELEMENT AND PIEZOELECTRIC PUMP

(75) Inventors: Shinya NAGAO, Yasu-shi (JP); Toshio NISHIMURA, Yasu-shi (JP); Masanaga NISHIKAWA, Kanazawa-shi (JP)

Correspondence Address: MURATA MANUFACTURING COMPANY, LTD.;C/O KEATING & BENNETT, LLP, 1800 Alexander Bell Drive, SUITE 200, Reston, VA, 20191, US

(73) Assignee: MURATA MANUFACTURING CO., LTD., Nagaokakyo-shi (JP)

(21) Appl. No.: 12/796,764

(22) Filed: Jun. 9, 2010

Related U.S. Application Data
(63) Continuation of application No. PCT/JP2009/001698, filed on Apr. 13, 2009.

(30) Foreign Application Priority Data
Apr. 17, 2008 (JP) 2008-107759

(51) Int. Cl. F04B 17/03; H01L 41/047

(52) U.S. Cl. 417/413.2; 310/366

(57) ABSTRACT

A piezoelectric element that is capable of achieving a larger amount of displacement and in which migration between electrodes hardly occurs, is included in a piezoelectric pump. The piezoelectric pump includes a first excitation electrode opposed to a second excitation electrode via a first piezoelectric layer in a central area of a layered piezoelectric body, a third excitation electrode opposed to a fourth excitation electrode via a second piezoelectric layer and a third excitation electrode opposed to a fourth excitation electrode via the second piezoelectric layer in peripheral portions of the layered piezoelectric body. A polarization direction and a direction in which an electric field is applied in a first driving area where the first excitation electrode opposes the second excitation electrode are equal to a polarization direction and a direction in which the electric field is applied in second driving areas where the third excitation electrode opposes the fourth excitation electrode and the third excitation electrode opposes the fourth excitation electrode, and bending and displacement in the layered piezoelectric element where the second excitation electrode is isolated from the third excitation electrodes and in a thickness direction and in a central portion of the layered piezoelectric element are used to discharge liquid.

### BACKGROUND OF THE INVENTION

1. Field of the Invention

The present invention relates to layered piezoelectric elements used in, for example, piezoelectric pumps and to piezoelectric pumps. More particularly, the present invention relates to a layered piezoelectric element in which a central portion is bent and displaced in a direction opposite to the direction in which peripheral portions surrounding the central portion are bent and displaced and to a piezoelectric pump including such a layered piezoelectric element.

2. Description of the Related Art

Piezoelectric pumps that use piezoelectric elements to discharge liquids, etc., are known. A typical piezoelectric pump includes a pump main body including a pump chamber and a piezoelectric element that is fixed to the pump main body so as to close an opening of the pump chamber. When a voltage is applied to bend and displace the piezoelectric element, the displacement of the piezoelectric element causes the volume of the pump chamber to be varied. As a result, the liquid is led to the pump chamber or is discharged from the pump chamber.

In order to achieve a larger amount of discharge, the center portion of the piezoelectric element is required to be greatly displaced.

In the above situation, Japanese Unexamined Patent Application Publication No. 3-54383 discloses a piezoelectric pump using a piezoelectric element shown in FIG. 13. As shown in FIG. 13, in a piezoelectric element 1001, a first piezoelectric body 1002 is adhered to a second piezoelectric body 1003 via a metal plate 1004. A central electrode 1005 and peripheral electrodes 1006 are formed on the top surface of the piezoelectric body 1002. A central electrode 1007 and peripheral electrodes 1008 are formed also on the bottom surface of the piezoelectric body 1003.

One end of an alternating-current power supply 1009 is electrically connected to the metal plate 1004 serving as a common electrode. The other end of the alternating-current power supply 1009 is electrically connected to the peripheral electrodes 1006 and 1008 via a controller 1010 and is electrically connected to the central electrodes 1005 and 1007 via an inverter 1011.

The first and second piezoelectric bodies 1002 and 1003 are wholly polarized in the same thickness direction, as shown by arrows P.

A voltage applied to the central electrodes 1005 and 1007 is out of phase with a voltage applied to the peripheral electrodes 1006 and 1008 by 180 degrees.

Accordingly, the direction of an electric field E applied to the central portion is opposite to the directions of the electric fields E applied to the peripheral portions in each of the piezoelectric bodies 1002 and 1003. Accordingly, if an expansion displacement occurs in the central portion of the piezoelectric body 1002 as shown in FIG. 13, the central portion of the piezoelectric body 1003 is subjected to contraction displacement. In addition, the peripheral portions of the first piezoelectric body 1002 are subjected to the contraction displacement while the peripheral portions of the second piezoelectric body 1003 are subjected to the expansion displacement.

Consequently, great displacement can be achieved in the central portion in the piezoelectric element 1001.

However, since the voltage applied to the central electrode 1005 formed on the external surface of the first piezoelectric body 1002 is different from the voltage applied to the peripheral electrodes 1006 formed thereon, a short circuit due to migration can occur between the central electrode 1005 and the peripheral electrodes 1006. Similarly, a short circuit can occur between the central electrode 1007 and the peripheral electrodes 1008 also on the bottom surface of the second piezoelectric body 1003.

In addition, a drive circuit becomes complicated because it is necessary to provide the complicated wiring and further to provide the inverter 1011, as shown in FIG. 13.

In contrast, WO Publication 2008/007634 discloses a piezoelectric pump using a piezoelectric element shown in FIG. 14. A piezoelectric element 1101 shown in FIG. 14 includes a layered piezoelectric ceramic body 1105 in which first and second piezoelectric layers 1102 and 1103 are layered via an electrode 1104.

A central electrode 1106 and peripheral electrodes 1107 are formed on the top surface of the layered piezoelectric ceramic body 1105. A central electrode 1108 and peripheral electrodes 1109 are formed on the bottom surface of the layered piezoelectric ceramic body 1105. The central portion is polarized in a direction from the top surface of the layered piezoelectric ceramic body 1105 to the bottom surface thereof, as shown by arrows P in FIG. 14. In contrast, the peripheral portions are polarized in a direction opposite to the polarization direction of the central portion in the thickness direction. In other words, the peripheral portions are polarized in a direction from the bottom surface of the layered piezoelectric ceramic body 1105 to the top surface thereof.

In driving, a first voltage is applied to the central electrode 1106 and the peripheral electrodes 1109, a second voltage is applied to the central electrode 1108 and the peripheral electrodes 1107, and a third voltage having a magnitude between the magnitude of the first voltage and that of the second voltage is applied to the electrode 1104. In other words, the first voltage > the third voltage > the second voltage.

Accordingly, also in the piezoelectric element 1101, if the first piezoelectric layer 1102 is subjected to the expansion displacement, the central portion of the second piezoelectric layer 1103 is subjected to the contraction displacement and the peripheral portions are displaced in a direction opposite to the displacement direction of the central portion in the first and second piezoelectric layers. Consequently, it is possible to increase the amount of displacement in the central portion also in the piezoelectric element 1101.

As described above, although the piezoelectric element used in the piezoelectric pump is strongly required to increase the amount of displacement in the central portion, it is not possible to sufficiently meet such a requirement with the piezoelectric element 1001 described in Japanese Unexamined Patent Application Publication No. 3-54383.

In the piezoelectric element 1001, the central portion of the first piezoelectric body 1002 is displaced in a direction opposite to the displacement direction of the central portion of the second piezoelectric body 1003, as described above. However, the electric field is applied to either of the piezoelectric bodies in a direction opposite to the polarization direction in the driving. For example, in the state shown in FIG. 13, the polarization direction P is opposite to the direction in which the electric field E is applied in the central portion of the first piezoelectric body 1002. Accordingly, it is not possible to greatly increase the strength of the applied electric field E. In other words, it is necessary to make the driving electric field smaller than the coercive electric field E because application of a driving electric field having a magnitude greater than that of the coercive electric field causes depolarization. Consequently, it is difficult to achieve great displacement.

In contrast, in the piezoelectric element 1101 shown in FIG. 14, since the electric potential to which the central electrode 1106 is connected is different from the electric potential to which the peripheral electrodes 1107 are connected, migration can occur between the central electrode 1106 and the peripheral electrodes 1107. Similarly, since the electric potential to which the central electrode 1108 is connected is different from the electric potential to which the peripheral electrodes 1109 are connected, migration can occur between the central electrode 1108 and the peripheral electrodes 1109.

### SUMMARY OF THE INVENTION

To overcome the problems described above, preferred embodiments of the present invention provide a piezoelectric element which is capable of increasing the driving voltage to achieve a larger amount of displacement and in which migration between electrodes hardly occurs and also provide a piezoelectric pump including such a piezoelectric element.

According to a preferred embodiment of the present invention, a layered piezoelectric element includes a layered piezoelectric body including a first piezoelectric layer, a second piezoelectric layer, and a third piezoelectric layer layered between the first and second piezoelectric layers; first and second excitation electrodes that are opposed to each other with the first piezoelectric layer of the piezoelectric body sandwiched therebetween and that are positioned in a central area when the first piezoelectric layer is viewed in plan; and third and fourth excitation electrodes that are opposed to each other with the second piezoelectric layer sandwiched therebetween and that are arranged in areas around the area where the first and second excitation electrodes are provided. A portion of the first piezoelectric layer in a first driving area in which the first excitation electrode is overlapped with the second excitation electrode via the first piezoelectric layer is polarized in a thickness direction of the layered piezoelectric body and a portion of the second piezoelectric layer in a second driving area in which the third excitation electrode is overlapped with the fourth excitation electrode via the second piezoelectric layer is polarized in the same direction as in the first driving area.

In a specific aspect of the layered piezoelectric element according to a preferred embodiment of the present invention, a fourth piezoelectric layer is layered outside at least one of the first and second piezoelectric layers in a layering direction. In this case, since at least either of the first and second excitation electrodes and the third and fourth excitation electrodes is covered with the fourth piezoelectric layer, a short circuit between the first and second excitation electrodes and/or a short circuit between the third and fourth excitation electrodes hardly occurs. In addition, since liquid is hardly in contact with the first and second excitation electrodes and/or the third and fourth excitation electrodes, these excitation electrodes are hardly corroded.

In another specific aspect of the layered piezoelectric element according to a preferred embodiment of the present invention, no piezoelectric layer is provided outside the first and second piezoelectric layers, the second excitation electrode is disposed on an external surface of the first piezoelectric layer, and the third excitation electrode is disposed on an external surface of the second piezoelectric layer. As in the above case, it is acceptable not to provide the fourth piezoelectric layer. In this case, the manufacturing process can be simplified and the amount of displacement can be increased because the fourth piezoelectric layer does not exist.

In another specific aspect of the layered piezoelectric element according to a preferred embodiment of the present invention, all of the piezoelectric layers preferably are uniformly polarized in the thickness direction. In this case, the polarization can be easily performed.

In a preferred embodiment of the present invention, in the first and second driving areas, the first and second piezoelectric layers may be polarized in the thickness direction and a portion of the piezoelectric body excluding the first and second driving areas may not be polarized.

In addition, in another specific aspect of the layered piezoelectric element according to a preferred embodiment of the present invention, when viewed in plan, the first and second driving areas are arranged so that an outer margin of the first driving area is in contact with a margin of the second driving area at the side of the first driving area. In this case, it is possible to reduce the size of the layered piezoelectric element.

In a preferred embodiment of the present invention, when viewed in plan, an outer margin of the first driving area may be isolated from a margin of the second driving area at the side of the first driving area and a buffering portion may be arranged between the first and second driving areas. In this case, the presence of the buffering portion can produce a larger amount of displacement.

In the layered piezoelectric element according to a preferred embodiment of the present invention, a pair of second driving areas may be arranged on both sides of the first driving area or the second driving area may be arranged so as to surround the first driving area.

In another specific aspect of the layered piezoelectric element according to a preferred embodiment of the present invention, the first and second excitation electrodes each preferably have a square or rectangular planar shape and the third and fourth excitation electrodes each preferably have a rectangular planar shape, for example. In this case, it is possible to easily and accurately form the excitation electrodes each having a square or rectangular planar shape by printing with conductive paste or the like, for example.

A piezoelectric pump according to a preferred embodiment of the present invention includes a pump main body that includes a pump chamber and a piezoelectric element that is held in the pump main body so as to close the pump chamber and that is bent and displaced in response to a voltage that is applied to vary the volume of the pump chamber. The portion of the piezoelectric element closing the pump chamber includes a central portion and peripheral portions surrounding the central portion. In the piezoelectric pump in which a center portion is bent and displaced in a direction opposite to the direction in which a driving portion is bent and displaced in response to a driving voltage that is applied, the piezoelectric element includes the layered piezoelectric element structured in accordance with a preferred embodiment of the present invention.

In the above-described piezoelectric pump, the layered piezoelectric element can be fixed and held in various manners. Even if the layered piezoelectric element is fixed at the peripheral portions, a larger amount of displacement can be achieved at the central portion. In a specific aspect, the layered piezoelectric element is fixed on one side of the diaphragm, and a plane opposite the plane of the diaphragm at which the layered piezoelectric element is fixed is arranged so as to close the pump chamber. In other words, the unimorph piezoelectric resonator includes the layered piezoelectric element and the diaphragm, thus achieving a much larger amount of displacement. In this case, the piezoelectric element may include the diaphragm and the layered piezoelectric element and may be fixed at a margin of the diaphragm. Alternatively, the piezoelectric element may be fixed at margins of both of the diaphragm and the layered piezoelectric element.

In the layered piezoelectric element according to a preferred embodiment of the present invention, the portions that are driven by a piezoelectric effect when a voltage is applied correspond to the first driving area and the second driving areas, the first driving area is positioned at the central portion and the second driving areas are positioned at the peripheral portions, the first and second driving areas are arranged in the first and second piezoelectric layers, respectively, and both of the driving areas have the same polarization direction and the same direction in which the electric field is applied. Accordingly, it is possible to apply a driving voltage having a magnitude greater than that of a coercive electric field to both of the first and second driving areas. Consequently, even if the layered piezoelectric element is fixed at peripheral portions, it is possible to achieve a larger amount of displacement in a central area.

In addition, since the excitation electrodes connected different voltages do not exist in planes at the same height in the layered piezoelectric element, migration between the electrodes hardly occurs.

Consequently, the use of the layered piezoelectric element according to a preferred embodiment of the present invention allows the amount of discharge in, for example, the piezoelectric pump to be increased and allows the reliability to be improved because a failure due to the migration between the electrodes hardly occurs.

Other elements, features, steps, characteristics and advantages of the present invention will become more apparent from the following detailed description of the preferred embodiments with reference to the attached drawings.

### BRIEF DESCRIPTION OF THE DRAWINGS

FIG. 1A and FIG. 1B are a perspective view and a front cross-sectional view for describing a layered piezoelectric element according to a first preferred embodiment of the present invention and FIG. 1C is a schematic front cross-sectional view illustrating a displacement state.

FIG. 2 includes exploded perspective views of the layered piezoelectric element according to the first preferred embodiment of the present invention.

FIG. 3 is a schematic plan view of a piezoelectric pump according to a preferred embodiment of the present invention.

FIG. 4 is a cross-sectional view taken along line X-X in FIG. 3.

FIG. 5 is a cross-sectional view taken along line Y-Y in FIG. 3.

FIG. 6 illustrates the relationship between a driving voltage and the amount of displacement when the layered piezoelectric element of the first preferred embodiment is driven.

FIG. 7 is a front cross-sectional view illustrating a layered piezoelectric element according to a second preferred embodiment of the present invention.

FIG. 8 is a front cross-sectional view illustrating a layered piezoelectric element according to a third preferred embodiment of the present invention.

FIG. 9 is a front cross-sectional view illustrating a layered piezoelectric element according to a fourth preferred embodiment of the present invention.

FIG. 10 is a front cross-sectional view illustrating a layered piezoelectric element according to a fifth preferred embodiment of the present invention.

FIG. 11 is a perspective view illustrating a mother layered body from which the layered piezoelectric element of the first preferred embodiment is produced.

FIG. 12 includes exploded perspective views for describing a modification of the piezoelectric element of the present invention.

FIG. 13 is a schematic view illustrating an example of a piezoelectric element used in a piezoelectric pump in the related art.

FIG. 14 is a schematic view illustrating a piezoelectric element used in another example of the piezoelectric pump in the related art.

### DETAILED DESCRIPTION OF THE PREFERRED EMBODIMENTS

Specific preferred embodiments of the present invention will herein be described with reference to the attached drawings to disclose the present invention.

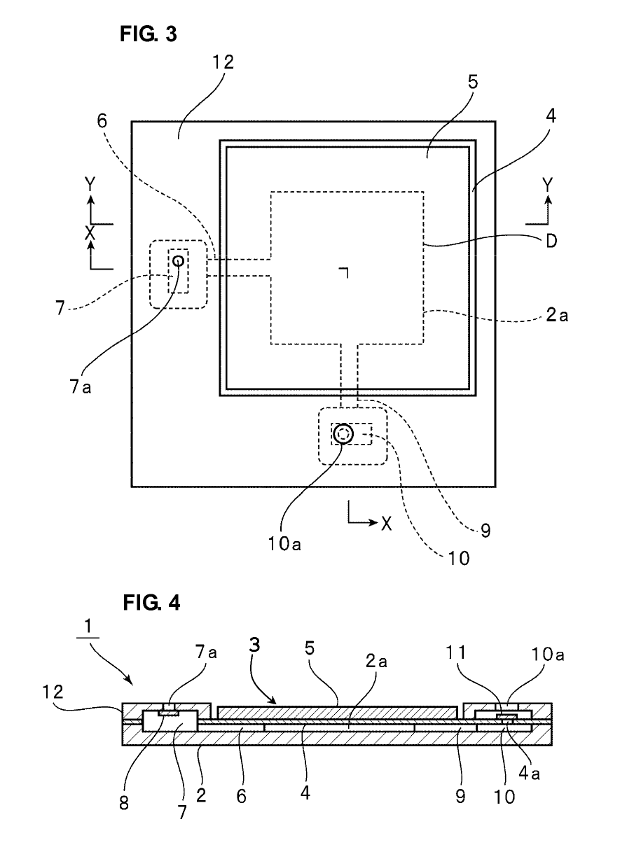

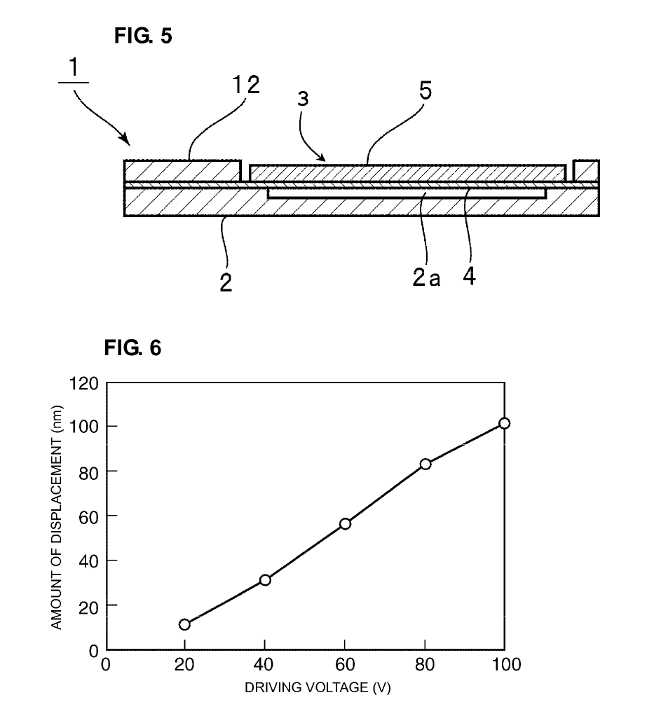

FIG. 3 is a schematic plan view of a piezoelectric pump according to a preferred embodiment of the present invention. FIG. 4 is a cross-sectional view taken along line X-X in FIG. 3. FIG. 5 is a cross-sectional view taken along line Y-Y in FIG. 3.

A piezoelectric pump 1 includes a pump main body 2. The pump main body 2 includes a plate member having a depression on its top surface in the present preferred embodiment. The pump main body 2 is preferably made of a material, such as metal or synthetic resin, for example, having a relatively high rigidity.

A piezoelectric element 3 is arranged so as to close the depression of the pump main body 2. The piezoelectric element 3 has a unimorph structure in which a layered piezoelectric element 5 is fixed on the top surface of a diaphragm 4 defined by a metal plate. The layered piezoelectric element 5 will be described in detail below.

The depression of the pump main body 2 is closed with the piezoelectric element 3 to define a pump chamber 2a.

A margin of the diaphragm 4 is sandwiched between the top surface of the pump main body 2 and a pressure plate 12 to be fixed. Accordingly, the unimorph piezoelectric element 3 is mechanically held along a margin.

If a central portion of the piezoelectric element 3, specifically, a central portion of the layered piezoelectric element 5 is bent and displaced, the volume of the pump chamber 2a is varied. For example, if the central portion of the layered piezoelectric element 5 is displaced so as to protrude downward, the volume of the pump chamber 2a is decreased.

An entry-side valve chest 7 is connected to the pump chamber 2a via a connection channel 6. The entry-side valve chest 7 has an entry-side check valve 8 arranged therein. The entry-side check valve 8 is mounted so as to close an opening 7a provided at an upper portion of the entry-side valve chest 7. In suction of liquid, the entry-side check valve 8 is opened to lead the liquid to the entry-side valve chest 7. The entry-side check valve 8 prevents the liquid in the entry-side valve chest 7 from flowing toward the opening 7a.

At the other side, an exit-side valve chest 10 is connected to the pump chamber 2a via a connection channel 9. An exit-side check valve 11 is arranged under an opening 10a of the exit-side valve chest 10. The exit-side check valve 11 is fixed to the top surface of the diaphragm 4 so as to close an opening 4a provided in the diaphragm 4. The exit-side check valve 11 permits the liquid to move to the upper side of the diaphragm 4 but prevents the liquid from moving toward the connection channel 9 through the opening 4a.

Although the pump chamber 2a preferably has a rectangular planar shape in this preferred embodiment, the pump chamber 2a may have another shape. For example, the pump chamber 2a may have a circular planar shape.

In the piezoelectric pump 1, if the piezoelectric element 3 is bent and displaced, the volume of the pump chamber 2a is varied to cause inflow or discharge of the liquid. For example, if the central portion of the layered piezoelectric element 5 is displaced so as to protrude downward, the volume of the pump chamber 2a is decreased. Returning to an initial state shown in FIG. 4 and FIG. 5 from the above state causes the volume of the pump chamber 2a to be increased. As a result, the pressure in the pump chamber 2a is decreased to lead the liquid into the entry-side valve chest 7 and further lead the liquid into the pump chamber 2a through the connection channel 6.

If the central portion of the layered piezoelectric element 5 is bent and displaced again so as to protrude downward, the volume of the pump chamber 2a is decreased. As a result, the liquid in the pump chamber 2a is moved toward the exit-side valve chest 10 and is discharged from the opening 10a.

In order to increase the amount of discharge of the liquid in the piezoelectric pump 1, the layered piezoelectric element 5 is strongly required to increase its amount of displacement.

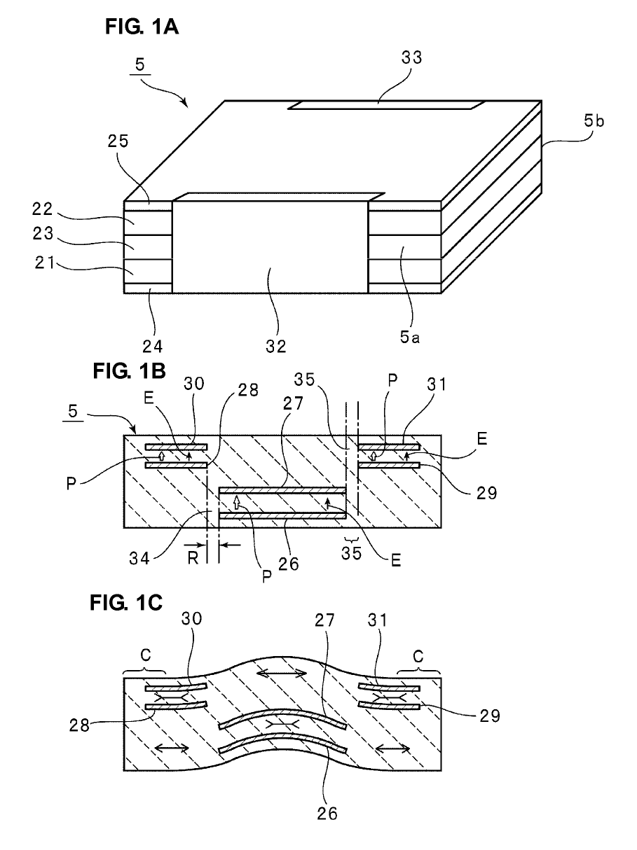

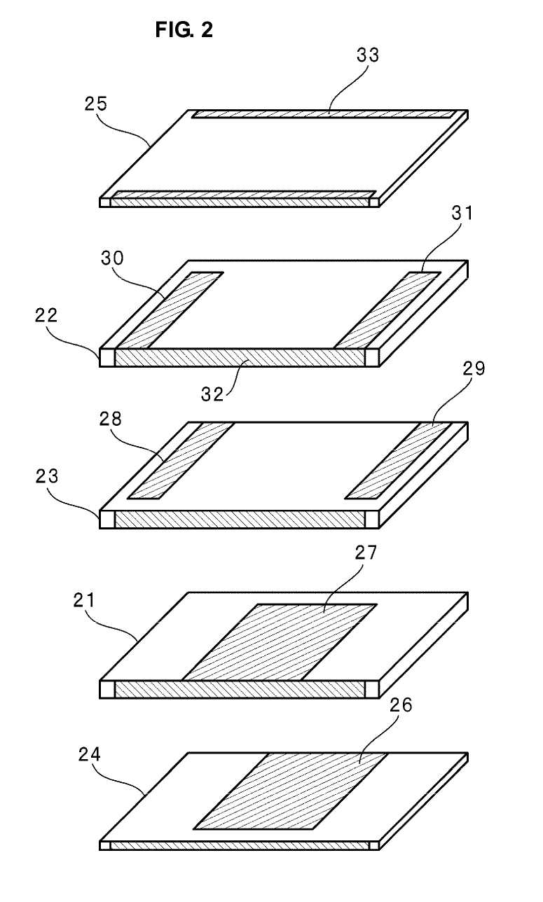

A layered piezoelectric element according to a first preferred embodiment of the present invention will now be described with reference to FIGS. 1A to 1C and FIG. 2.

As shown in FIG. 1A, the layered piezoelectric element 5 preferably includes a monolithic layered piezoelectric body manufactured with a ceramic-internal electrode co-firing technology. The layered piezoelectric element 5 can be reduced in thickness and cost because the layered piezoelectric element 5 is not manufactured by adhering piezoelectric bodies that are fired in advance to each other.

In this layered piezoelectric body, a first piezoelectric layer 21 is layered on a second piezoelectric layer 22 via a third piezoelectric layer 23. A fourth piezoelectric layer 24 is layered underneath the first piezoelectric layer 21. A fourth piezoelectric layer 25 is also layered on the second piezoelectric layer 22.

As shown in an exploded perspective view in FIG. 2, a square or substantially square first excitation electrode 26 is disposed under the bottom surface of the first piezoelectric layer 21, that is, on the top surface of the fourth piezoelectric layer 24. A second excitation electrode 27 having a square or substantially square shape as in the first excitation electrode 26 is arranged so as to oppose the first excitation electrode 26 via the first piezoelectric layer 21. The first and second excitation electrodes 26 and 27 may have a rectangular shape or may have another suitable shape, such as a circular or triangular shape, for example.

The first and second excitation electrodes 26 and 27 are each positioned in a central area with the layered piezoelectric element 5 viewed in plan. The central area is an area including the center in the plan view and is an area that is positioned on the inner side of the plan view, compared with peripheral portions described below.

In contrast, third excitation electrodes 28 and 29 are provided on the top surface of the third piezoelectric layer 23, that is, under the bottom surface of the second piezoelectric layer 22. The third excitation electrodes 28 and 29 are positioned in the peripheral areas with the layered piezoelectric element 5 viewed in plan. In other words, the third excitation electrodes 28 and 29 are arranged so as not to be overlapped with the first and second excitation electrodes 26 and 27 in the thickness direction.

Fourth excitation electrodes 30 and 31 are arranged so as to be overlapped with the third excitation electrodes 28 and 29, respectively, via the second piezoelectric layer 22.

As shown in FIG. 1A, a first terminal electrode 32 is disposed on one side surface 5a of the layered piezoelectric element 5 and a second terminal electrode 33 is disposed on another side surface 5b thereof. The second excitation electrode 27 and the fourth excitation electrodes 30 and 31 described above extend toward the one side surface 5a to be electrically connected to the first terminal electrode 32. In contrast, the first excitation electrode 26 and the third excitation electrodes 28 and 29 extend toward the other side surface 5b to be electrically connected to the second terminal electrode 33.

In addition, as shown by arrows P in FIG. 1B, a first driving area sandwiched between the first and second excitation electrodes 26 and 27 is polarized in the thickness direction in the present preferred embodiment. Second driving areas sandwiched between the third excitation electrode 28 and the fourth excitation electrode 30 and between the third excitation electrode 29 and the fourth excitation electrode 31 are also polarized in the thickness direction. The first driving area has the same polarization direction as those of the second driving areas. The polarization direction is directed from the bottom to the top in the thickness direction of the layered piezoelectric element 5 in the present preferred embodiment.

The portion of the piezoelectric body excluding the first and second driving areas is preferably not polarized. Accordingly, during the polarization, a polarization voltage is applied between the first and second excitation electrodes 26 and 27, between the third excitation electrode 28 and the fourth excitation electrode 30, and between the third excitation electrode 29 and the fourth excitation electrode 31 for the polarization.

In order to manufacture the layered piezoelectric body, conductive paste is applied on ceramic green sheets primarily made of appropriate piezoelectric ceramic powder to manufacture the ceramic green sheets on which the first, second, third, and fourth excitation electrodes are formed. These ceramic green sheets are layered and a plain ceramic green sheet on which the fourth piezoelectric layer 25 is layered on these ceramic green sheets to attach the layers by pressure in the thickness direction. Then, after the resulting layered body is fired or before the resulting layered body is fired, the first and second terminal electrodes 32 and 33 are formed.

The above ceramic green sheets are produced by sheet forming of ceramic green paste primarily made of appropriate piezoelectric ceramic powder, such as lead zirconate titanate ceramics, for example. The excitation electrodes 26 to 31 are preferably formed by printing with conductive paste, such as Ag or Ag—Pd paste, for example, on the ceramic green sheets and baking of the ceramic green sheets in the firing.

The terminal electrodes 32 and 33 can preferably be formed of appropriate metal, such as Ag, Cu, or Ag—Pd, for example. The terminal electrodes 32 and 33 may be formed by a thin film forming method, such as deposition, plating, or sputtering, for example, instead of the application and baking of the conductive paste.

The above piezoelectric ceramics and the metallic material of which the electrodes are composed are not particularly restricted.

In the layered piezoelectric element 5 of the present preferred embodiment, the central portion is greatly bent and displaced when the layered piezoelectric element 5 is fixed in areas denoted by C in FIG. 1C.

In other words, as shown in FIG. 1B, the polarization direction of the first driving area is the same as those of the second driving areas. When a direct-current voltage is applied between the first terminal electrode 32 and the second terminal electrode 33, for example, when electric fields are applied in a manner shown by arrows E in FIG. 1B, the displacement shown in FIG. 1C is caused. The symbols representing the displacement in FIG. 1C have the same meanings as the displacement symbols shown in a lower portion of FIG. 13.

Accordingly, since the polarization direction P is equal to the direction E in which the electric fields are applied in the first and second driving areas, the displacement occurs so as to cause lateral contraction, as shown in FIG. 1C. Consequently, in the first piezoelectric layer 21, the first driving area, that is, the central area is subjected to contraction displacement and the peripheral portions at both sides of the central area are subjected to expansion displacement.

Inversely, in the second piezoelectric layer 22, the second driving areas, that is, the peripheral portions are subjected to the contraction displacement and the central area sandwiched between the second driving areas is subjected to the expansion displacement. Accordingly, since the peripheral portions are displaced in a direction opposite to the displacement direction of the central portion in both of the first and second piezoelectric layers 21 and 22, greater bending and displacement is produced in the central portion when the layered piezoelectric element 5 is fixed in the peripheral portions denoted by C.

In addition, since the polarization direction P is equal to the direction E in which the electric fields are applied in the layered piezoelectric element 5 of the present preferred embodiment, a voltage having a magnitude greater than that of a coercive electric field can be applied to the layered piezoelectric element 5 to drive the layered piezoelectric element 5, so that a larger amount of displacement can be achieved.

Accordingly, in FIG. 3 and FIG. 5, since the margin of the diaphragm 4 is sandwiched between the pump main body 2 and the pressure plate 12 to fix the piezoelectric element 3, the margin side of the layered piezoelectric element 5 is also fixed via the diaphragm 4. In other words, the central portion of the layered piezoelectric element 5, which is positioned on the pump chamber 2a, can be bent and displaced together with the diaphragm 4. Broken lines D in FIG. 3 correspond to the planar shape of the pump chamber 2a, and the planar shape of the first driving area of the layered piezoelectric element 5 is substantially matched with that of the pump chamber 2a. The portion bordering the pump chamber 2a can preferably be set as the first driving area in the above manner to greatly vary the volume of the pump chamber 2a.

The first driving area of the layered piezoelectric element 5 is not necessarily matched with the pump chamber 2a in the planar shape. The pump chamber 2a may have a planar shape larger than that of the first driving area or may be smaller than the planar shape of the first driving area.

In addition, although the margin of the diaphragm 4 is sandwiched between the pressure plate 12 and the pump main body 2 to fix the margin of the diaphragm 4 in the present preferred embodiment, a structure may be adopted in which the margin of the layered piezoelectric element 5 is further fixed with the pressure plate 12 or other suitable structure.

Furthermore, the multiple electrodes at the same height are not connected to different voltages in the layered piezoelectric element 5. For example, the third excitation electrodes 28 and 29 are connected to the same voltage and the fourth excitation electrodes 30 and 31 are connected to the same voltage. Accordingly, migration does not occur between the multiple electrodes formed at the same height. In addition, since the first and second excitation electrodes 26 and 27 are formed at heights different from those of the third and fourth excitation electrode 28 to 31, migration does not occur between the first and second excitation electrodes 26 and 27 and the third and fourth excitation electrodes 28 to 31.

Specifically, since the third piezoelectric layer 23 is arranged between the first piezoelectric layer 21 and the second piezoelectric layer 22, the second excitation electrode 27 is isolated from the third excitation electrodes 28 and 29 in the layering direction, that is, in the thickness direction of the layered piezoelectric element 5. Accordingly, migration does not occur between the third excitation electrodes 28 and 29 and the second excitation electrode 27.

Furthermore, since the first excitation electrode 26 and the fourth excitation electrodes 30 and 31 are covered with the fourth piezoelectric layers 24 and 25, respectively, a short circuit due to contact with liquid is prevented and corrosion of the excitation electrodes is also prevented.

FIG. 6 is a diagram illustrating how the amount of displacement of a piezoelectric element is varied with the varying driving voltage in the layered piezoelectric element 5 of the present preferred embodiment. As apparent from FIG. 6, when the driving voltage is increased from 20 V to 100 V, for example, the amount of displacement is increased with the increasing voltage.

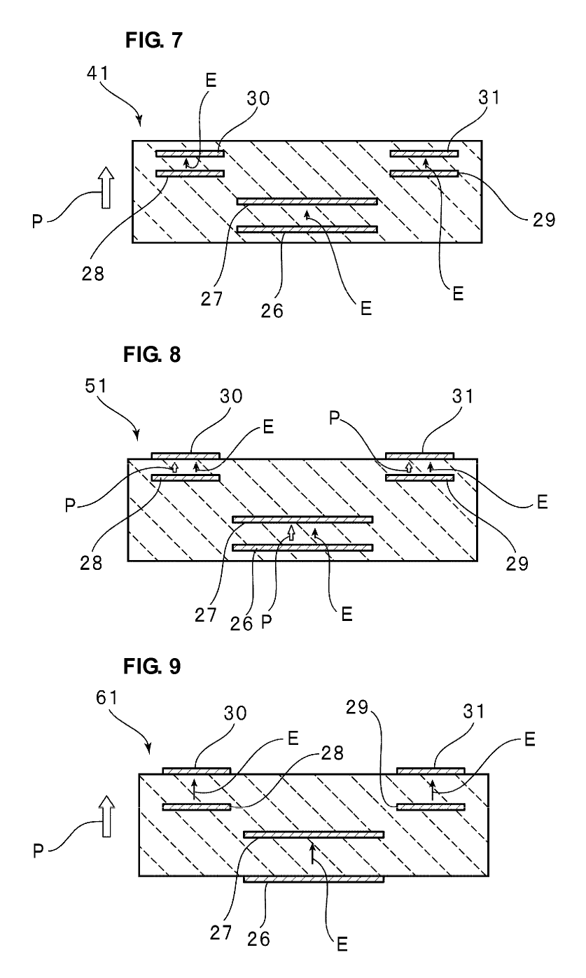

FIG. 7 is a schematic front cross-sectional view for describing a layered piezoelectric element according to a second preferred embodiment of the present invention.

A layered piezoelectric element 41 of the second preferred embodiment is similar to the layered piezoelectric element 5 of the first preferred embodiment except that the entire layered piezoelectric element is subjected to the polarization processing in a direction from the bottom to the top, as shown by an arrow P. In the layered piezoelectric element 5 of the first preferred embodiment, the piezoelectric body is polarized only in the first and second driving areas. Accordingly, in the polarization, the polarization voltage is applied between the first and second excitation electrodes 26 and 27, between the third excitation electrode 28 and the fourth excitation electrode 30, and between the third excitation electrode 29 and the fourth excitation electrode 31 for the polarization. In contrast, the entire layered piezoelectric element is uniformly subjected to the polarization processing in the second preferred embodiment. Accordingly, in the polarization, polarization electrodes are provided on the top surface and the bottom surface after the layered piezoelectric body is manufactured and a voltage is applied between the polarization electrodes for the polarization processing. In this case, the polarization electrodes on the top surface and the bottom surface are removed after the polarization processing. However, the polarization electrodes may not be removed.

Although it is necessary to separately form the polarization electrodes in the second preferred embodiment, the polarization can be easily performed because it is sufficient to uniformly polarize the entire layered piezoelectric body at a stage at which a mother layered piezoelectric body is manufactured.

FIG. 8 is a front cross-sectional view illustrating a layered piezoelectric element 51 according to a third preferred embodiment of the present invention. The layered piezoelectric element 51 of the third preferred embodiment is similar to the layered piezoelectric element 5 of the first preferred embodiment except that the fourth piezoelectric layer 25 is not provided and the fourth excitation electrodes 30 and 31 are externally exposed on the top surface of the layered piezoelectric element 51. As in FIG. 8, the fourth piezoelectric layer 25 may not be formed. In this case, it is possible to increase the amount of displacement because a binding force of the fourth piezoelectric layer 25 is not exerted.

A printing method or other suitable method is used to form the fourth excitation electrodes 30 and 31 on the top surface of the layered piezoelectric element 51. However, with the printing method, it is difficult to form the fourth excitation electrodes 30 and 31 so as to exactly overlap the lower excitation electrodes 28 and 29. A shift in the printing position can cause the amount of displacement in the second driving areas to be reduced so as to reduce the amount of displacement by contraries.

In contrast, in the first and second preferred embodiments, the multiple ceramic green sheets to which the printing with the conductive paste is subjected are layered so that the first excitation electrode exactly opposes the second excitation electrode and the third excitation electrodes exactly oppose the fourth excitation electrodes. It is easier to increase the accuracy of the layering than to increase the accuracy of the printing positions. Accordingly, according to the present preferred embodiment, it is possible to further reduce the variation in the amount of displacement and to suppress a reduction in the amount of displacement.

FIG. 9 is a front cross-sectional view illustrating a layered piezoelectric element according to a fourth preferred embodiment of the present invention. A layered piezoelectric element 61 is similar to the layered piezoelectric element 5 of the first preferred embodiment except that both of the lower and upper fourth piezoelectric layers 24 and 25 are not provided. Since the lower and upper fourth piezoelectric layers 24 and 25 are not provided, binding forces due to the fourth piezoelectric layers 24 and 25 are not exerted. However, since the first excitation electrode 26 is also externally exposed on the external surface, the amount of displacement can possibly be reduced due to a shift in the positions where the electrodes are formed, compared with the layered piezoelectric element 51 of the third preferred embodiment.

In addition, since the first excitation electrode 26 and the fourth excitation electrodes 30 and 31 are externally exposed, a short circuit or corrosion due to adhesion of liquid may occur.

In contrast, such a short circuit or corrosion is prevented in the first and second preferred embodiments. Accordingly, the layered piezoelectric elements 5 and 41 of the first and second preferred embodiments are preferable.

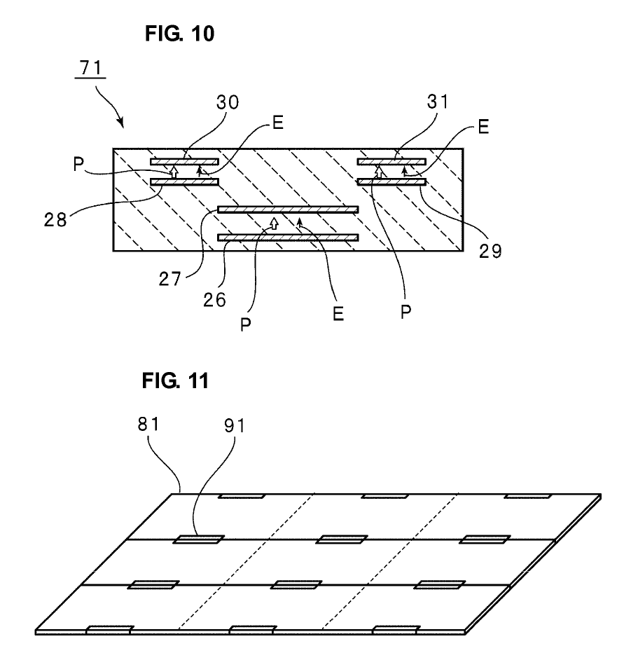

FIG. 10 is a front cross-sectional view illustrating a layered piezoelectric element 71 according to a fifth preferred embodiment of the present invention.

In the layered piezoelectric element 5 of the first preferred embodiment, buffering portions 34 and 35 are arranged between the first driving area and the second driving areas. In other words, a certain distance R is kept between edges of the first and second excitation electrodes 26 and 27 and the opposing edges of the third and fourth excitation electrodes 28 and 30 in a portion where the first and second excitation electrodes 26 and 27 are adjacent to the third and fourth excitation electrodes 28 and 30 in the lateral direction in FIG. 1B to provide the buffering portion 34 between the first and second driving areas. Similarly, the buffering portion 35 is provided between the first and second excitation electrodes 26 and 27 and the third and fourth excitation electrodes 29 and 31.

Accordingly, the presence of the buffering portions 34 and 35 produces greater bending and displacement in the central area.

However, as in the fifth preferred embodiment shown in FIG. 10, the buffering portions may not be provided. In the fifth preferred embodiment in FIG. 10, no buffering portion is provided between the first and second excitation electrodes 26 and 27 and the third and fourth excitation electrodes 28 and 30, and the outer edges of the first and second excitation electrodes 26 and 27 are positioned at the same positions as the inner edges, opposing the above outer edges, of the third and fourth excitation electrodes 28 and 30, viewed in plan. Similarly, the outer edges of the first and second excitation electrodes 26 and 27 are positioned at the same positions as the inner edges, opposing the above outer edges, of the third and fourth excitation electrodes 29 and 31, viewed in plan. Accordingly, the buffering portions 34 and 35 shown in FIG. 1B are not provided. In this case, although the amount of displacement at the center is somewhat decreased, the lateral dimension is decreased and, thus, a layered piezoelectric element 71 can be reduced in size.

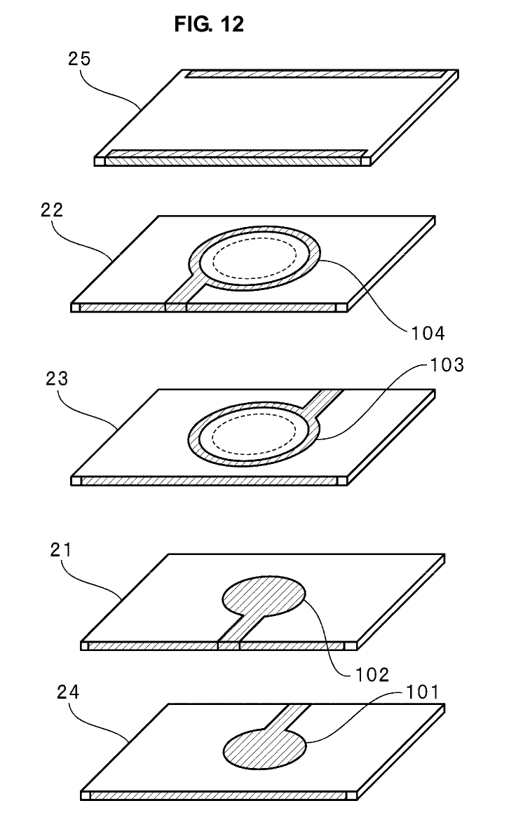

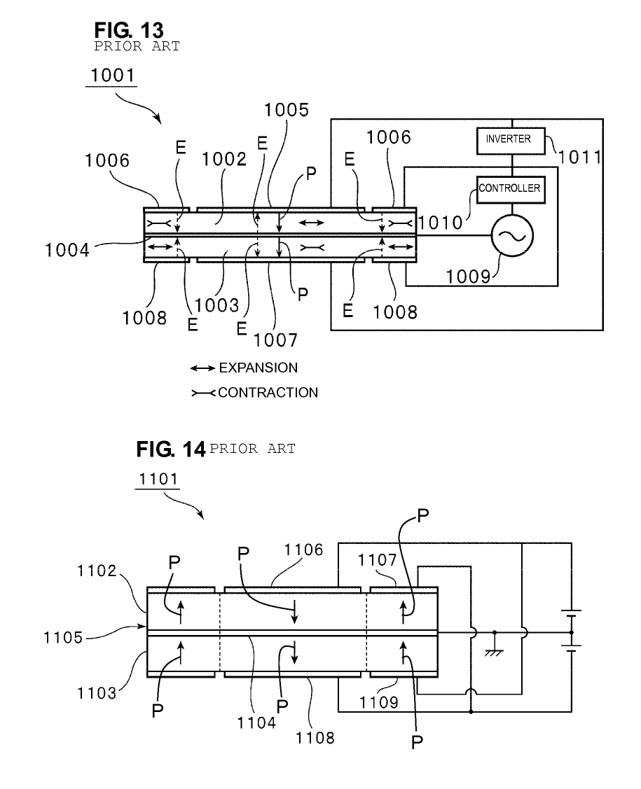

In the manufacturing of each of the layered piezoelectric elements of various preferred embodiments of the present invention, as shown in FIG. 11, a mother layered piezoelectric body 81 is manufactured and then is longitudinally and laterally divided, so that the individual layered piezoelectric element can be manufactured with increased productivity.

In this case, electrodes 91 each defining portions of the terminal electrodes 32 and 33 are formed in advance and, after the division, the remaining electrode portions are formed so as to continue into the electrode 91 on side surfaces of the layered piezoelectric body in order to form the terminal electrodes 32 and 33.

Although the third and fourth excitation electrodes each preferably having a rectangular planar shape, for example, are arranged outside the square first and second excitation electrodes 26 and 27 in the above preferred embodiments, circular first and second excitation electrodes 101 and 102 and ring-shaped peripheral electrodes 103 and 104 may be used as in a modification shown in exploded perspective views in FIG. 12. In other words, the planar shapes of the first and second excitation electrodes arranged at the center portions are not particularly restricted. In addition, the third and fourth excitation electrodes corresponding to the peripheral electrodes may have various shapes including rectangle, square, and ring. Alternatively, the third and fourth excitation electrodes may each have a shape resulting from cutting out a portion of a ring shape or a rectangular annulus.

While preferred embodiments of the present invention have been described above, it is to be understood that variations and modifications will be apparent to those skilled in the art without departing the scope and spirit of the present invention. The scope of the present invention, therefore, is to be determined solely by the following claims.

What is claimed is:

1. A layered piezoelectric element comprising:
a layered piezoelectric body including a first piezoelectric layer, a second piezoelectric layer, and a third piezoelectric layer layered between the first and second piezoelectric layers;
first and second excitation electrodes that are opposed to each other with the first piezoelectric layer of the piezoelectric body sandwiched therebetween, and that are positioned in a central area of the first piezoelectric layer when the first piezoelectric layer is viewed in plan so as to define a first driving area; and
third and fourth excitation electrodes that are opposed to each other with the second piezoelectric layer sandwiched therebetween and that are arranged in areas around the area in which the first and second excitation electrodes are positioned so as to define a second driving area; wherein
a portion of the first piezoelectric layer in the first driving area in which the first excitation electrode is overlapped with the second excitation electrode via the first piezoelectric layer is polarized in a thickness direction of the layered piezoelectric body; and
a portion of the second piezoelectric layer in the second driving area in which the third excitation electrode is overlapped with the fourth excitation electrode via the second piezoelectric layer is polarized in the same direction as that of the first driving area.

2. The layered piezoelectric element according to claim 1, wherein a fourth piezoelectric layer is arranged outside at least one of the first and second piezoelectric layers in a layering direction.

3. The layered piezoelectric element according to claim 1, wherein no piezoelectric layer is provided outside of the first and second piezoelectric layers, the second excitation electrode is disposed on an external surface of the first piezoelectric layer, and the third excitation electrode is disposed on an external surface of the second piezoelectric layer.

4. The layered piezoelectric element according to claim 1, wherein all of the piezoelectric layers are uniformly polarized in the thickness direction.

5. The layered piezoelectric element according to claim 1, wherein, in the first and second driving areas, the first and second piezoelectric layers are polarized in the thickness direction and the portion of the piezoelectric body excluding the first and second driving areas is not polarized.

6. The layered piezoelectric element according to claim 1, wherein, when viewed in plan, the first and second driving areas are arranged so that an outer margin of the first driving area is aligned with a margin of the second driving area at a side of the first driving area.

7. The layered piezoelectric element according to claim 1, wherein, when viewed in plan, an outer margin of the first driving area is spaced away from a margin of the second driving area at a side of the first driving area and a buffering portion is arranged between the first and second driving areas.

8. The layered piezoelectric element according to claim 1, wherein a pair of the second driving areas are arranged on both sides of the first driving area.

9. The layered piezoelectric element according to claim 1, wherein the first and second excitation electrodes each have a substantially square or a substantially rectangular planar shape and the third and fourth excitation electrodes each have a substantially rectangular planar shape.

10. A piezoelectric pump comprising:
a pump main body including a depression and a piezoelectric element that is arranged in the pump main body so as to close the depression to define a pump chamber and that is bent and displaced in response to a voltage that is applied to the piezoelectric element to vary a volume of the pump chamber; wherein
a portion of the piezoelectric element closing the depression includes a central portion and peripheral portions surrounding the central portion, and the central portion is bent and displaced in response to the voltage that is applied to the piezoelectric element so as to vary the volume of the pump chamber; and
the piezoelectric element includes the layered piezoelectric element according to claim 1.

11. The piezoelectric pump according to claim 10, wherein the piezoelectric element further includes a diaphragm, the layered piezoelectric element is fixed on one surface of the diaphragm, and a surface opposite to the surface of the diaphragm at which the layered piezoelectric element is fixed is arranged to close the depression.
